(19) United States
(12) Patent Application Publication
(10) Pub. No.: US 2022/0035980 A1
(43) Pub. Date: Feb. 3, 2022

(54) TRANSISTOR MODEL, METHOD FOR FORMING TRANSISTOR MODEL, SIMULATION DEVICE, PROGRAM, AND RECORDING MEDIUM

(71) Applicant: SEMICONDUCTOR ENERGY LABORATORY CO., LTD., Atsugi-shi, Kanagawa-ken (JP)

(72) Inventors: Hitoshi KUNITAKE, Isehara, Kanagawa (JP); Kazuki TSUDA, Atsugi, Kanagawa (JP); Tatsuki KOSHIDA, Nanao, Ishikawa (JP); Takeya HIROSE, Atsugi, Kanagawa (JP); Tomoaki ATSUMI, Hadano, Kanagawa (JP)

(21) Appl. No.: 17/299,654

(22) PCT Filed: Nov. 20, 2019
(86) PCT No.: PCT/IB2019/059954

§ 371 Date: Jun. 3, 2021

(30) Foreign Application Priority Data
Dec. 27, 2018 (JP) 2018-244755

(51) Int. Cl. G06F 30/367

(52) U.S. Cl. CPC G06F 30/367; H01L 29/78696

(57) ABSTRACT

A transistor model that achieves precise approximation of transistor electrical characteristics is provided. The transistor model is a field-effect transistor model. A first capacitor is provided between a gate and a source. A second capacitor is provided between the gate and a drain. Each of the first capacitor and the second capacitor is a non-linear capacitor whose capacitance value is determined depending on a gate voltage. The first capacitor may be composed of a plurality of variable capacitors. The second capacitor may be composed of a plurality of variable capacitors. When CV characteristics of the first capacitor and CV characteristics of the second capacitor are adjusted, more precise simulation data is obtained.

### TECHNICAL FIELD

One embodiment of the present invention relates to a transistor model, a method for forming a transistor model, a simulation device, a program, a recording medium, and the like.

Note that one embodiment of the present invention is not limited to the above technical field. The technical field of the invention disclosed in this specification and the like relates to an object, a method, or a manufacturing method. Alternatively, one embodiment of the present invention relates to a process, a machine, manufacture, or a composition of matter.

### BACKGROUND ART

In recent years, circuit simulators such as SPICE (Simulation Program with Integrated Circuit Emphasis) have been used in circuit design using transistors. The circuit simulators have functions of verifying a variety of circuit operations by simulation. The simulation is performed using a device model that is made to approximate electrical characteristics of a transistor, a diode, a capacitor, a resistor, or the like. In order to improve simulation accuracy, the accuracy of the device model needs to be improved. In particular, a device model that is made to precisely approximate electrical characteristics of a non-linear element (for example, a diode or a transistor) is needed.

Electrical characteristics of a transistor vary depending on the structure of the transistor. Thus, different transistor models have been proposed (for example, see Patent Document 1).

A field-effect transistor has characteristics in which a capacitance value and a resistance value between a source and a drain change depending on a gate voltage. Thus, in order to verify the operation of a circuit using the transistor accurately, it is necessary to reproduce changes in characteristics of capacitance and resistance accurately.

### PRIOR ART DOCUMENT

### Patent Document

[Patent Document 1] Japanese Published Patent Application No. 2001-160622

### SUMMARY OF THE INVENTION

### Problems to be Solved by the Invention

However, in a conventional transistor model that is made to approximate voltage changes with the threshold voltage used as a reference, characteristics approximation cannot be performed when there are a plurality of inflection points with respect to voltage dependence of a current and capacitance. For example, characteristics approximation of a transistor whose semiconductor layers are formed using a stack of semiconductor layers having different electron affinities cannot be performed.

An object of one embodiment of the present invention is to provide a transistor model that achieves precise approximation of transistor electrical characteristics. Another object is to provide a method for forming the transistor model. Another object is to provide a program for executing the transistor model on a computer. Another object is to provide a simulation device that achieves the transistor model. Another object is to provide a program that makes a computer function as the simulation device.

Note that the description of these objects does not preclude the existence of other objects. Note that one embodiment of the present invention does not have to achieve all these objects. Note that objects other than these will be apparent from the description of the specification, the drawings, the claims, and the like, and objects other than these can be derived from the description of the specification, the drawings, the claims, and the like.

### Means for Solving the Problems

One embodiment of the present invention is a transistor model that is made to approximate characteristics of a field-effect transistor including a gate, a source, and a drain. A first capacitor is provided between the gate and the source. A second capacitor is provided between the gate and the drain. Each of the first capacitor and the second capacitor is a variable capacitor whose capacitance value is determined depending on a gate voltage.

Another embodiment of the present invention is a method for forming a transistor model that is made to approximate characteristics of a field-effect transistor. The method for forming a transistor model includes a first step of setting a field-effect transistor model that includes a gate, a source, and a drain; a second step of setting a first capacitor between the gate and the source; and a third step of setting a second capacitor between the gate and the drain. Each of the first capacitor and the second capacitor is a variable capacitor whose capacitance value is determined depending on a gate voltage. The method for forming a transistor model includes a fourth step of making CV characteristics of the first capacitor and CV characteristics of the second capacitor approximate measured values of CV characteristics of gate capacitance of the field-effect transistor.

Another embodiment of the present invention is a program for executing the method for forming a transistor model on a computer. Another embodiment of the present invention is a computer readable recording medium that stores the program.

Another embodiment of the present invention is a simulation device that is made to approximate characteristics of a field-effect transistor. The simulation device has a function of setting a field-effect transistor model that includes a gate, a source, and a drain; a function of setting a first capacitor between the gate and the source; and a function of setting a second capacitor between the gate and the drain. Each of the first capacitor and the second capacitor is a variable capacitor whose capacitance value is determined depending on a gate voltage. The simulation device has a function of making CV characteristics of the first capacitor and CV characteristics of the second capacitor approximate measured values of CV characteristics of gate capacitance of the field-effect transistor.

Another embodiment of the present invention is a program that makes a computer function as the simulation device.

Another embodiment of the present invention is a computer readable recording medium that stores the program.

The first capacitor may be composed of a plurality of capacitors. The second capacitor may be composed of a plurality of capacitors.

### Effect of the Invention

According to one embodiment of the present invention, it is possible to provide a transistor model that achieves precise approximation of transistor electrical characteristics. Alternatively, it is possible to provide a method for forming the transistor model. Alternatively, it is possible to provide a program for executing the transistor model on a computer. Alternatively, it is possible to provide a simulation device that achieves the transistor model. Alternatively, it is possible to provide a program that makes a computer function as the simulation device.

Note that the description of these effects does not preclude the existence of other effects. Note that one embodiment of the present invention does not have to have all these effects. Note that effects other than these will be apparent from the description of the specification, the drawings, the claims, and the like, and effects other than these can be derived from the description of the specification, the drawings, the claims, and the like.

### BRIEF DESCRIPTION OF THE DRAWINGS

FIG. 1A, FIG. 1B, and FIG. 1C are equivalent circuit diagrams of a transistor model.

FIG. 2A and FIG. 2B are diagrams illustrating a transistor structure example.

FIG. 3A1, FIG. 3A2, FIG. 3B1, and FIG. 3B2 are diagrams showing gate voltage dependence of gate capacitance.

FIG. 4A and FIG. 4B are diagrams illustrating a transistor structure example.

FIG. 5A and FIG. 5B are diagrams illustrating a transistor structure example.

FIG. 6A and FIG. 6B are diagrams illustrating a transistor structure example.

FIG. 7 is a block diagram illustrating a simulation device structure example.

FIG. 8 is a flow chart showing a simulation device operation example.

FIG. 9A1, FIG. 9A2, FIG. 9B1, and FIG. 9B2 are diagrams showing measurement data and simulation data of CV characteristics of gate capacitance.

FIG. 10A and FIG. 10B are equivalent circuit diagrams of an inverter and a ring oscillator.

FIG. 11A, FIG. 11B, and FIG. 11C are diagrams showing measurement data and simulation data of the ring oscillator.

### MODE FOR CARRYING OUT THE INVENTION

Embodiments will be described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below. Note that in structures of the present invention described below, the same reference numerals are used in common for the same portions or portions having similar functions in different drawings, and a repeated description thereof is omitted.

In addition, the position, size, range, and the like of each component illustrated in the drawings and the like do not represent the actual position, size, range, and the like in some cases for easy understanding of the invention. Therefore, the disclosed invention is not necessarily limited to the position, size, range, or the like disclosed in the drawings and the like. For example, in an actual manufacturing process, a resist mask or the like might be unintentionally reduced in size by treatment such as etching, which is not reflected in some cases for easy understanding.

Furthermore, in a top view (also referred to as a plan view), a perspective view, or the like, the description of some components might be omitted for easy understanding of the drawings.

In addition, in this specification and the like, the terms “electrode” and “wiring” do not functionally limit these components. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, a “terminal” in an electric circuit refers to a portion that inputs or outputs a current, inputs or outputs a voltage, and/or receives or transmits a signal. Accordingly, part of a wiring or an electrode functions as a terminal in some cases.

Note that the term “over” or “under” in this specification and the like does not necessarily mean directly over or directly under regarding the positional relationship between components, nor limit the positional relationship to direct contact. For example, the expression “an electrode B over an insulating layer A” does not require the electrode B to be provided on and in direct contact with the insulating layer A, nor excludes the case where another component is provided between the insulating layer A and the electrode B.

In addition, functions of a source and a drain are interchanged with each other depending on operation conditions and the like, for example, when a transistor of different polarity is employed or when the current direction is changed in a circuit operation; therefore, it is difficult to define which is the source or the drain. Thus, the terms “source” and “drain” can be interchangeably used in this specification.

Furthermore, in this specification and the like, the expression “electrically connected” includes the case where components are directly connected and the case where components are connected through an “object having any electric action.” Here, there is no particular limitation on the “object having any electric action” as long as electrical signals can be transmitted and received between components that are connected through the object. Thus, even when the expression “electrically connected” is used, there is a case where no physical connection portion is made and a wiring is just extended in an actual circuit.

Furthermore, in this specification and the like, “parallel” indicates a state where two straight lines are placed at an angle of greater than or equal to −10° and less than or equal to 10°, for example. Accordingly, the case where the angle is greater than or equal to −5° and less than or equal to 5° is also included. Moreover, “perpendicular” and “orthogonal” indicate a state where two straight lines are placed at an angle of greater than or equal to 80° and less than or equal to 100°, for example. Accordingly, the case where the angle is greater than or equal to 85° and less than or equal to 95° is also included.

Note that in this specification and the like, the terms “identical,” “same,” “equal,” “uniform,” and the like used in describing calculation values and measurement values contain an error of ±10% unless otherwise specified.

In addition, a voltage refers to a potential difference between a certain potential and a reference potential (e.g., a ground potential or a source potential) in many cases. Therefore, the terms “voltage” and “potential” can be replaced with each other in many cases. In this specification and the like, the terms “voltage” and “potential” can be replaced with each other unless otherwise specified.

Note that even a “semiconductor” has characteristics of an “insulator” when conductivity is sufficiently low, for example. Thus, a “semiconductor” can be replaced with an “insulator.” In that case, a “semiconductor” and an “insulator” cannot be strictly distinguished from each other because a boundary therebetween is not clear. Accordingly, a “semiconductor” and an “insulator” described in this specification can be replaced with each other in some cases.

Furthermore, a “semiconductor” has characteristics of a “conductor” when conductivity is sufficiently high, for example. Thus, a “semiconductor” can be replaced with a “conductor.” In that case, a “semiconductor” and a “conductor” cannot be strictly distinguished from each other because a boundary therebetween is not clear. Accordingly, a “semiconductor” and a “conductor” in this specification can be replaced with each other in some cases.

Note that ordinal numbers such as “first” and “second” in this specification and the like are used in order to avoid confusion among components and do not denote some kind of sequential order or priority, such as the order of steps or the stacking order. In addition, a term without an ordinal number in this specification and the like might be provided with an ordinal number in the scope of claims in order to avoid confusion among components. Furthermore, a term with an ordinal number in this specification and the like might be provided with a different ordinal number in the scope of claims. Moreover, even when a term is provided with an ordinal number in this specification and the like, the ordinal number might be omitted in the scope of claims and the like.

Note that in this specification and the like, an “on state” of a transistor refers to a state in which a source and a drain of the transistor are electrically short-circuited (also referred to as a “conduction state”). Furthermore, an “off state” of the transistor refers to a state in which the source and the drain of the transistor are electrically disconnected (also referred to as a “non-conduction state”).

In addition, in this specification and the like, an “on-state current” sometimes refers to a current that flows between a source and a drain when a transistor is in an on state. Furthermore, an “off-state current” sometimes refers to a current that flows between a source and a drain when a transistor is in an off state.

In addition, in this specification and the like, a high power supply potential VDD (hereinafter also simply referred to as “VDD” or an “H potential”) is a power supply potential higher than a low power supply potential VSS. Furthermore, the low power supply potential VSS (hereinafter also simply referred to as “VSS” or an “L potential”) is a power supply potential lower than the high power supply potential VDD. Moreover, a ground potential can also be used as VDD or VSS. For example, in the case where VDD is a ground potential, VSS is a potential lower than the ground potential, and in the case where VSS is a ground potential, VDD is a potential higher than the ground potential.

In addition, in this specification and the like, a gate refers to part or the whole of a gate electrode and a gate wiring.

Furthermore, in this specification and the like, a source refers to part or all of a source region, a source electrode, or a source wiring. A source region refers to a region with a resistance value that is lower than or equal to a certain value in a semiconductor layer. A source electrode refers to part of a conductive layer that is connected to a source region.

Moreover, in this specification and the like, a drain refers to part or all of a drain region, a drain electrode, or a drain wiring. A drain region refers to a region with a resistance value that is lower than or equal to a certain value in a semiconductor layer. A drain electrode refers to part of a conductive layer that is connected to a drain region.

### Embodiment 1

In this embodiment, a transistor model according to one embodiment of the present invention will be described with reference to drawings.

### <Transistor Model>

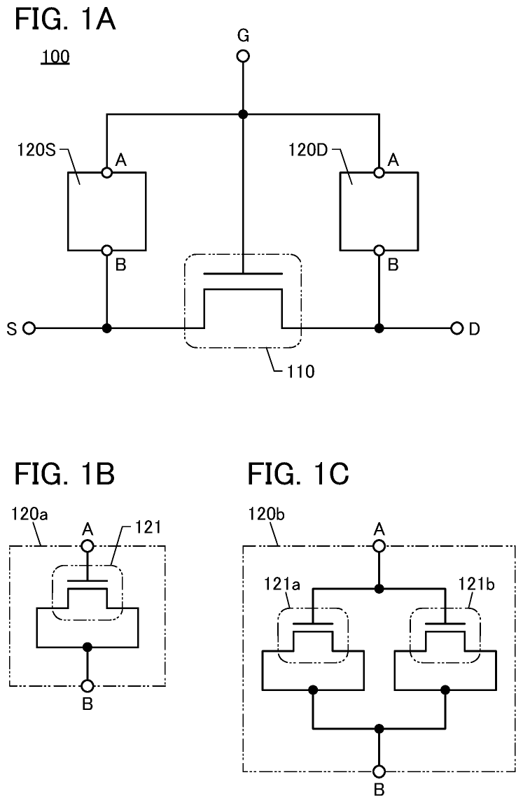

FIG. 1A is an equivalent circuit diagram of a transistor model 100 according to one embodiment of the present invention. The transistor model 100 includes a transistor 110, a capacitor 120S, and a capacitor 120D that are non-linear elements.

A gate of the transistor 110 is connected to a node G. A source of the transistor 110 is connected to a node S. A drain of the transistor 110 is connected to a node D. The capacitor 120S and the capacitor 120D each include a node A and a node B. The node A of the capacitor 120S is connected to the gate of the transistor 110, and the node B of the capacitor 120S is connected to the source of the transistor 110. The node A of the capacitor 120D is connected to the gate of the transistor 110, and the node B of the capacitor 120D is connected to the drain of the transistor 110.

A capacitor 120a and a capacitor 120b are described as structure examples of the capacitor 120S and the capacitor 120D. FIG. 1B is an equivalent circuit diagram illustrating a structure example of the capacitor 120a. The capacitor 120a can be composed of one transistor 121. Specifically, a gate of the transistor 121 is connected to the node A, and a source and a drain of the transistor 121 are connected to the node B. Thus, the transistor 121 functions as a MIS (Metal-Insulator-Semiconductor) capacitor. The node A is connected to the gate of the transistor 110; thus, the capacitor 120a functions as a non-linear capacitor whose capacitance value changes depending on a voltage applied to the gate of the transistor 110.

FIG. 1C is an equivalent circuit diagram illustrating a structure example of the capacitor 120b. The capacitor 120b can be composed of two transistors of a transistor 121a and a transistor 121b. Specifically, a gate of the transistor 121a is connected to the node A, and a source and a drain of the transistor 121a are connected to the node B. Thus, the transistor 121a functions as a MIS capacitor. In addition, a gate of the transistor 121b is connected to the node A, and a source and a drain of the transistor 121b are connected to the node B. Thus, the transistor 121b functions as a MIS capacitor. The node A is connected to the gate of the transistor 110; thus, the capacitor 120b functions as a non-linear capacitor whose capacitance value changes depending on a voltage applied to the gate of the transistor 110.

Note that one of the capacitor 120S and the capacitor 120D may be omitted. However, when both the capacitor 120S and the capacitor 120D are provided, simulation accuracy can be improved.

### [Transistor Structure Example]

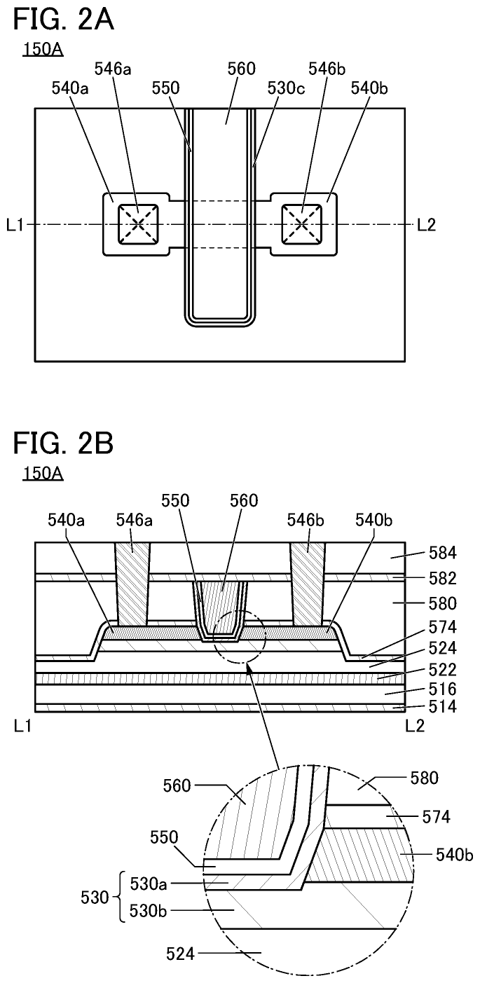

Here, an example of a transistor that can be applied to the transistor model 100 is described. A transistor 150A illustrated in FIG. 2A and FIG. 2B is an example of a transistor that can be applied to the transistor model 100 as a simulation model.

FIG. 2A is a plan view of the transistor 150A. FIG. 2B is a cross-sectional view of a portion indicated by dashed-dotted line L1-L2 in FIG. 2A. Note that in FIG. 2A, part of the description of components is omitted for simplification of the drawing.

In the transistor 150A, a semiconductor layer 530 is provided over an insulating layer 514, an insulating layer 516, an insulating layer 522, and an insulating layer 524. The semiconductor layer 530 includes a semiconductor layer 530a and a semiconductor layer 530b. A conductive layer 540a is provided to be in contact with part of the semiconductor layer 530b, and a conductive layer 540b is provided to be in contact with another part of the semiconductor layer 530b. In addition, an insulating layer 574, an insulating layer 580, an insulating layer 582, and an insulating layer 584 are provided over a conductive layer 540 (the conductive layer 540a and the conductive layer 540b).

In the transistor 150A, an opening is provided in parts of the conductive layer 540, the insulating layer 574, and the insulating layer 580, and the semiconductor layer 530a, an insulating layer 550, and a conductive layer 560 are provided along side surfaces and a bottom surface of the opening. The conductive layer 560 includes a region that overlaps with the semiconductor layer 530a with the insulating layer 550 therebetween. The semiconductor layer 530a includes a region that is in contact with the semiconductor layer 530b.

In addition, a conductive layer 546a and a conductive layer 546b are embedded in parts of the insulating layer 574, the insulating layer 580, the insulating layer 582, and the insulating layer 584. The conductive layer 546a and the conductive layer 546b function as contact plugs. The conductive layer 546a is electrically connected to the conductive layer 540a, and the conductive layer 546b is electrically connected to the conductive layer 540b.

The conductive layer 540a functions as one of a source electrode and a drain electrode, and the conductive layer 540b functions as the other of the source electrode and the drain electrode. The conductive layer 560 functions as a gate electrode. The insulating layer 550 functions as a gate insulating layer.

For each of the semiconductor layer 530a and the semiconductor layer 530b, a single crystal semiconductor, a polycrystalline semiconductor, a microcrystalline semiconductor, an amorphous semiconductor, or the like can be used alone or can be used in combination. As a semiconductor material, silicon, germanium, or the like can be used, for example. Alternatively, a compound semiconductor such as silicon germanium, silicon carbide, gallium arsenide, an oxide semiconductor, or a nitride semiconductor, an organic semiconductor, or the like can be used.

In addition, in the case where an organic semiconductor is used for the semiconductor layer, a low molecular organic material having an aromatic ring, a π-electron conjugated conductive polymer, or the like can be used. For example, rubrene, tetracene, pentacene, perylenediimide, tetracyanoquinodimethane, polythiophene, polyacetylene, polyparaphenylene vinylene, or the like can be used.

In addition, an oxide semiconductor, which is a kind of metal oxide, can be used for the semiconductor layer. The oxide semiconductor preferably contains at least indium (In) or zinc (Zn). In particular, In and Zn are preferably contained. Thus, an In oxide, a Zn oxide, an In—Zn oxide, or the like is used. Furthermore, aluminum (Al), gallium (Ga), yttrium (Y), tin (Sn), or the like is preferably contained in addition to them. Moreover, one kind or a plurality of kinds selected from boron (B), silicon (Si), titanium (Ti), iron (Fe), nickel (Ni), germanium (Ge), zirconium (Zr), molybdenum (Mo), lanthanum (La), cerium (Ce), neodymium (Nd), hafnium (Hf), tantalum (Ta), tungsten (W), magnesium (Mg), and the like may be contained.

In the case where an oxide semiconductor is used for the semiconductor layer, it is preferable to use an oxide semiconductor having a crystal part, such as a CAAC-OS or an nc-OS. CAAC-OS is an abbreviation for “C-Axis-Aligned Crystalline Oxide Semiconductor.” The CAAC-OS has c-axis alignment, a plurality of nanocrystals are connected in the a-b plane direction, and its crystal structure has distortion. Note that distortion refers to a portion where the direction of lattice arrangement changes between a region with regular lattice arrangement and another region with regular lattice arrangement in a region where the plurality of nanocrystals are connected. Nc-OS is an abbreviation for “nanocrystalline Oxide Semiconductor.”

### [CV Characteristics of Gate Capacitance]

In the case where electron affinities of semiconductor materials used for the semiconductor layer 530a and the semiconductor layer 530b are different, when the CV measurement of gate capacitance is performed, two threshold voltages (Vt) are inherent in obtained CV characteristics.

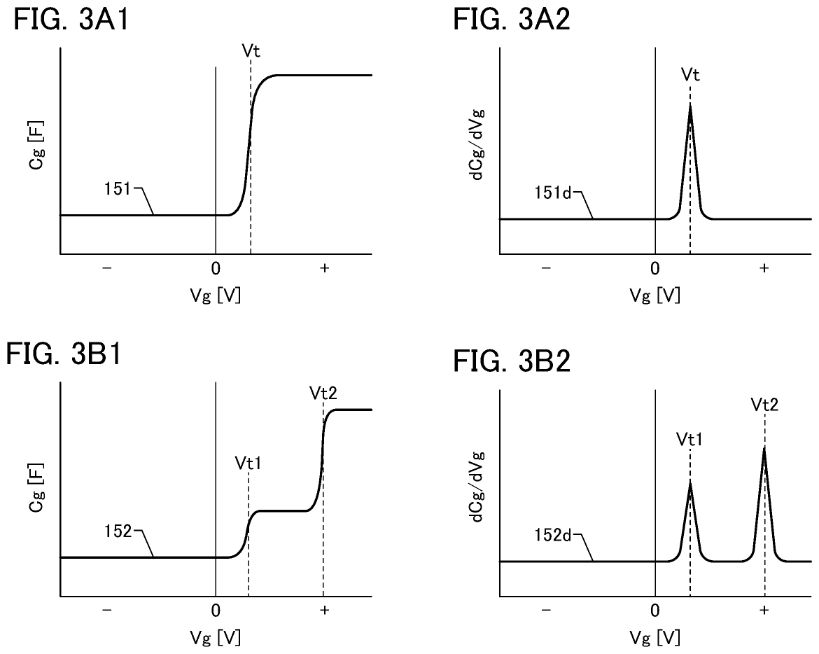

Here, CV characteristics of gate capacitance are described. CV characteristics of gate capacitance of a transistor are measured under the conditions that a source and a drain are set to a reference potential (0 V) and a gate voltage is changed from negative to positive (or from positive to negative). Each of FIG. 3A1 and FIG. 3B1 is a graph showing gate voltage (Vg) dependence of gate capacitance (Cg). In each of FIG. 3A1 and FIG. 3B1, a horizontal axis represents a linear axis showing a voltage value of the gate voltage (Vg), and a vertical axis represents a logarithmic axis showing a capacitance value of the gate capacitance (Cg).

FIG. 3A1 shows a CV curve 151 as an example of CV characteristics. FIG. 3B1 shows a CV curve 152 as an example of CV characteristics. In addition, FIG. 3A2 shows a differential curve 151d of the CV curve 151, and FIG. 3B2 shows a differential curve 152d of the CV curve 152. In each of FIG. 3A2 and FIG. 3B2, a horizontal axis represents a linear axis showing a voltage value of the gate voltage (Vg), and a vertical axis represents a linear axis showing the rate of change of the gate capacitance with respect to change of the gate voltage (dCg/dVg).

The CV curve 151 shown in FIG. 3A1 shows an example of CV characteristics when an oxide semiconductor having one electron affinity is used for the semiconductor layers. In the case where Vg continuously changes from negative to positive, when Vg exceeds a certain voltage, the value of Cg drastically increases, and then the value of Cg gets to saturation. Thus, one peak is observed in the differential curve 151d shown in FIG. 3A2. The peak corresponds to an inflection point of the CV curve 151. In this specification and the like, Vg at the peak position is denoted by Vt.

The CV curve 152 shown in FIG. 3B1 shows an example of CV characteristics when the semiconductor layers are formed using a stack of two semiconductor layers having different electron affinities. In that case, two peaks are observed, as shown in the differential curve 152d in FIG. 3B2. That is, two kinds of Vt exist. The two kinds of Vt in FIG. 3B1 and FIG. 3B2 are denoted by Vt1 and Vt2.

For example, in the case where semiconductor layers are formed using a stack of two semiconductor layers having different electron affinities like the transistor 150A, the capacitor 120a is used as the capacitor 120S and the capacitor 120D of the transistor model 100.

With the use of the capacitor 120a as the capacitor 120S and the capacitor 120D, the two kinds of Vt can be set for the transistor model 100.

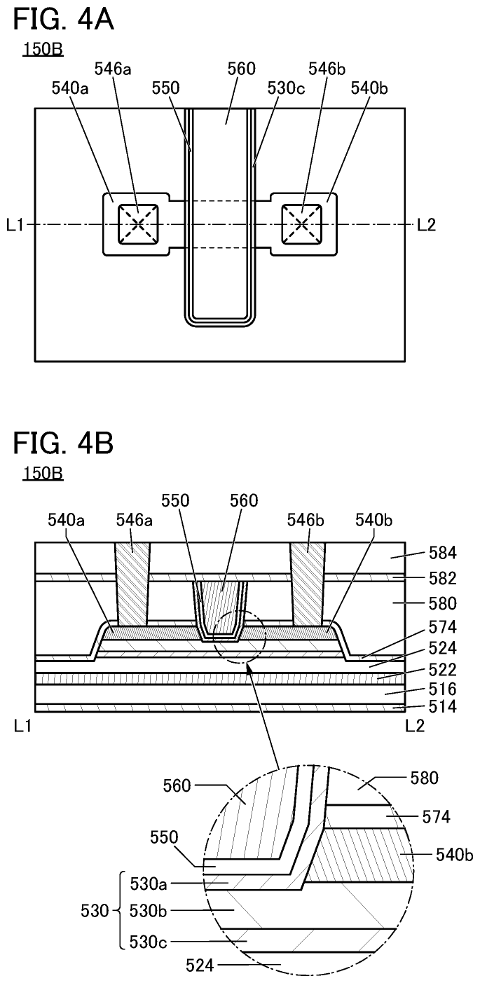

FIG. 4A and FIG. 4B illustrate another example of a transistor that can be applied to the transistor model 100. FIG. 4A is a plan view of a transistor 150B. FIG. 4B is a cross-sectional view of a portion indicated by dashed-dotted line L1-L2 in FIG. 4A. Note that in FIG. 4A, part of the description of components is omitted for simplification of the drawing.

The transistor 150B is a modification example of the transistor 150A. The transistor 150B differs from the transistor 150A in that the semiconductor layer 530 has a three-layer stack of the semiconductor layer 530a, the semiconductor layer 530b, and a semiconductor layer 530c.

For example, in the case where semiconductor layers are formed using a stack of three semiconductor layers having different electron affinities like the transistor 150B, the capacitor 120b is used as the capacitor 120S and the capacitor 120D of the transistor model 100.

With the use of the capacitor 120b as the capacitor 120S and the capacitor 120D, three kinds of Vt can be set for the transistor model 100.

Note that even in the case where the semiconductor layer 530 has a three-layer stacked structure, the capacitor 120a may be used as the capacitor 120S and the capacitor 120D depending on the electron affinity, film thickness, or the like of each of the semiconductor layer 530a, the semiconductor layer 530b, and the semiconductor layer 530c.

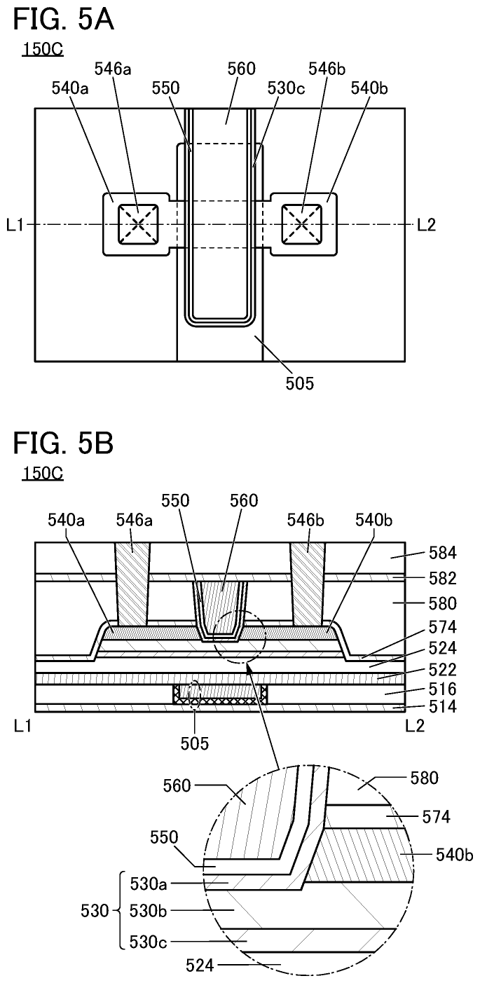

In addition, FIG. 5A and FIG. 5B illustrate another example of a transistor that can be applied to the transistor model 100. FIG. 5A is a plan view of a transistor 150C. FIG. 5B is a cross-sectional view of a portion indicated by dashed-dotted line L1-L2 in FIG. 5A. Note that in FIG. 5A, part of the description of components is omitted for simplification of the drawing.

The transistor 150C is a modification example of the transistor 150B. The transistor 150C differs from the transistor 150B in that a conductive layer 505 that can function as a back gate is included. The conductive layer 505 is embedded in the insulating layer 516. In the case where the conductive layer 505 functions as a back gate, the insulating layer 522 and the insulating layer 524 function as gate insulating layers.

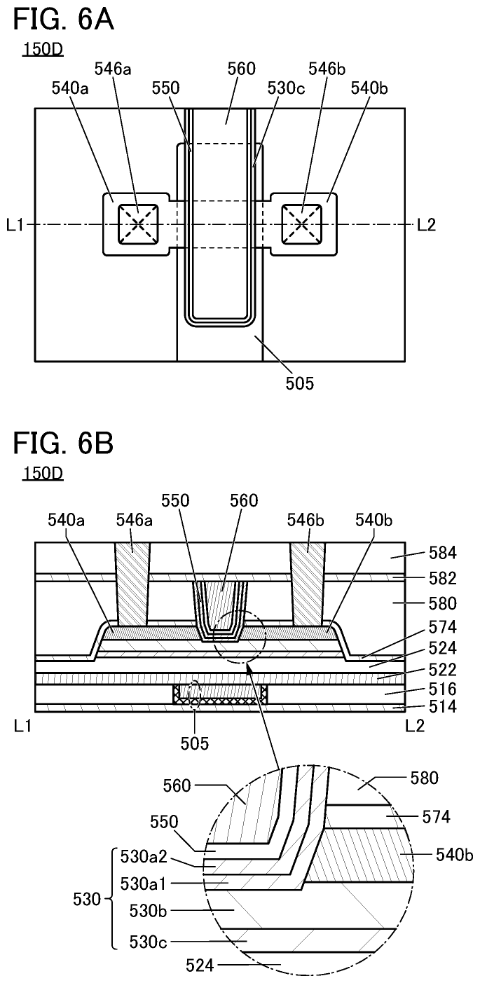

In addition, FIG. 6A and FIG. 6B illustrate another example of a transistor that can be applied to the transistor model 100. FIG. 6A is a plan view of a transistor 150D. FIG. 6B is a cross-sectional view of a portion indicated by dashed-dotted line L1-L2 in FIG. 6A. Note that in FIG. 6A, part of the description of components is omitted for simplification of the drawing.

The transistor 150D is a modification example of the transistor 150C. The transistor 150D differs from the transistor 150C in that the semiconductor layer 530 has a four-layer stack of a semiconductor layer 530a1, a semiconductor layer 530a2, the semiconductor layer 530b, and the semiconductor layer 530c.

For example, in the case where the semiconductor layers are formed using a stack of four semiconductor layers having different electron affinities like the transistor 150D, the transistor model 100 is used in which a capacitor that is similar to the capacitor 120a or the capacitor 120b is added to the capacitor 120b.

Note that even in the case where the semiconductor layer 530 has a four-layer stacked structure, the capacitor 120a or the capacitor 120b may be used as the capacitor 120S and the capacitor 120D depending on the electron affinity, film thickness, or the like of each of the semiconductor layer 530a1, the semiconductor layer 530a2, the semiconductor layer 530b, and the semiconductor layer 530c.

For example, in the case where materials having the same physical properties are used for the semiconductor layer 530a1 and the semiconductor layer 530a2 of the transistor 150D, the transistor 150D and the transistor 150C can be considered substantially the same transistors.

This embodiment can be implemented in an appropriate combination with structures described in the other embodiment, examples, and the like.

### Embodiment 2

In this embodiment, a simulation device 200 according to one embodiment of the present invention is described.

<Simulation Device>

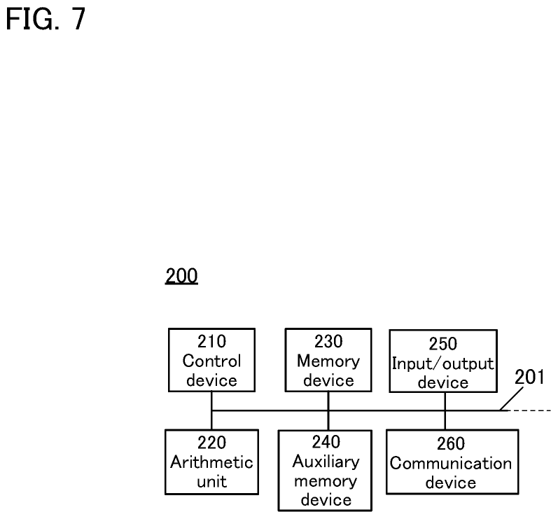

FIG. 7 is a block diagram illustrating a structure example of the simulation device 200. The simulation device 200 includes a control device 210, an arithmetic unit 220, a memory device 230, an auxiliary memory device 240, an input/output device 250, and a communication device 260. The devices are electrically connected to each other through a bus line 201.

### [Control Device 210 and Arithmetic Unit 220]

The control device 210 has a function of controlling operations of the other devices. In addition, the arithmetic unit 220 has a function of executing arithmetic processing for simulation. A central processing unit (CPU) or the like can be used as the arithmetic unit 220, for example.

Furthermore, the control device 210 and/or the arithmetic unit 220 may be achieved using a PLD (Programmable Logic Device) such as an FPGA (Field Programmable Gate Array) or an FPAA (Field Programmable Analog Array).

An arithmetic result obtained in the arithmetic unit 220 is output to the memory device 230 and/or the auxiliary memory device 240. In addition, the arithmetic result obtained in the arithmetic unit 220 is output to a display device (not illustrated), a printer, or the like through the input/output device 250 and/or the communication device 260.

### [Memory Device 230]

The memory device 230 has a function of storing programs and parameters for simulation operations, and at least part of the memory device 230 is preferably a rewritable memory. For example, the memory device 230 can have a structure where a volatile memory such as a RAM (Random Access Memory) or a nonvolatile memory such as a ROM (Read Only Memory) is provided.

For example, a DRAM (Dynamic Random Access Memory) is used as a RAM provided in the memory device 230. A memory space is assigned to part of the RAM as a workspace of the simulation device 200. An operating system, an application program, data, and the like that are stored in the auxiliary memory device 240 are read into the RAM for execution.

### [Auxiliary Memory Device 240]

The auxiliary memory device 240 is a memory device that stores an operating system, an application program, data, and the like. In addition, a variety of parameters that are used in the arithmetic unit 220 are sometimes stored in the auxiliary memory device 240.

As the auxiliary memory device 240, a memory device employing a nonvolatile memory element, such as a flash memory, an MRAM (Magnetoresistive Random Access Memory), a PRAM (Phase change RAM), an ReRAM (Resistive RAM), or an FeRAM (Ferroelectric RAM); a memory device employing a volatile memory element, such as a DRAM (Dynamic RAM) or an SRAM (Static RAM); or the like may be used, for example. Alternatively, a memory media drive such as a hard disc drive (HDD) or a solid state drive (SSD) may be used, for example.

Alternatively, for example, a memory device that can be detached through the input/output device 250, such as an HDD or an SSD, may be used as the auxiliary memory device 240. Alternatively, a media drive for a recording medium such as a Blu-ray disc or a DVD can be used as the auxiliary memory device 240.

Note that in the case where a memory device placed outside the simulation device 200 is used as the auxiliary memory device 240, a structure may be employed in which data is input and output to and from the simulation device 200 through wireless communication using the communication device 260.

### [Input/Output Device 250]

The input/output device 250 has a function of inputting and outputting signals between an external device and the simulation device 200. In addition, an HDMI (registered trademark) terminal, a USB terminal, a LAN (Local Area Network) connection terminal, or the like may be used as an external port of the input/output device 250. Furthermore, the input/output device 250 may have a transmitting/receiving function for optical communication using infrared rays, visible light, ultraviolet rays, or the like.

### [Communication Device 260]

The communication device 260 can perform communication via an antenna. For example, the communication device 260 controls a control signal for connecting the simulation device 200 to a computer network in response to instructions from the arithmetic unit 220 and transmits the signal to the computer network. Accordingly, communication can be performed by connection of the simulation device 200 to a computer network such as the Internet, which is the infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network). In the case where a plurality of communication methods are used, a plurality of antennas may be provided depending on the communication methods.

The communication device 260 is provided with a high frequency circuit (RF circuit), for example, to transmit and receive RF signals. The high frequency circuit is a circuit for performing mutual conversion between an electromagnetic signal and an electrical signal in a frequency band that is set by national laws to perform wireless communication with another communication device using the electromagnetic signal. As a practical frequency band, several tens of kilohertz to several tens of gigahertz are generally used. A structure can be employed in which the high frequency circuit connected to an antenna includes a high frequency circuit portion compatible with a plurality of frequency bands and the high frequency circuit portion includes an amplifier, a mixer, a filter, a DSP (Digital Signal Processor), an RF transceiver, or the like. In the case of performing wireless communication, it is possible to use, as a communication protocol or a communication technology, a communication standard such as LTE (Long Term Evolution), GSM (Global System for Mobile Communication: registered trademark), EDGE (Enhanced Data Rates for GSM Evolution), CDMA 2000 (Code Division Multiple Access 2000), or WCDMA (Wideband Code Division Multiple Access: registered trademark), or a specification that is communication standardized by IEEE, such as Wi-Fi (registered trademark), Bluetooth (registered trademark), or ZigBee (registered trademark).

A computer that includes the control device 210, the arithmetic unit 220, the memory device 230, the auxiliary memory device 240, and an output device 250 or the communication device 260 can function as the simulation device 200. For example, when a signal for starting a simulation program according to one embodiment of the present invention is input to the control device 210 through the input/output device 250 or the communication device 260, the control device 210 outputs a signal for reading a simulation program stored in the auxiliary memory device 240 into the memory device 230. When the simulation program is read into the memory device 230, the computer can function as the simulation device.

In addition, the control device 210 outputs a signal for reading a variety of data, such as setting parameters input through the input/output device 250 or the communication device 260, into the memory device 230. The arithmetic unit 220 executes arithmetic processing by using the program, data, or the like read into the memory device 230. Note that the auxiliary memory device 240 can also be used as the memory device 230. Furthermore, a cache that is provided in the arithmetic unit 220 may be used as the memory device 230.

A BIOS (Basic Input/Output System), firmware, and the like for which rewriting is not needed can be stored in a ROM. As the ROM, a mask ROM, an OTPROM (One Time Programmable Read Only Memory), an EPROM (Erasable Programmable Read Only Memory), or the like can be used. Examples of the EPROM include a UV-EPROM (Ultra-Violet Erasable Programmable Read Only Memory) that can erase stored data by ultraviolet irradiation, an EEPROM (Electrically Erasable Programmable Read Only Memory), and a flash memory.

Part or all of the simulation program may be stored in the ROM.

### <Operation Example of Simulation Device>

Then, an operation example of the simulation device 200 is described. The simulation device 200 can generate a variety of device models such as a transistor model, a diode model, a capacitor model, and a resistor model. In addition, the simulation device 200 can reproduce operation characteristics similar to those of an actual device by using a generated device model. Furthermore, a combination of generated device models can reproduce a variety of circuit operations.

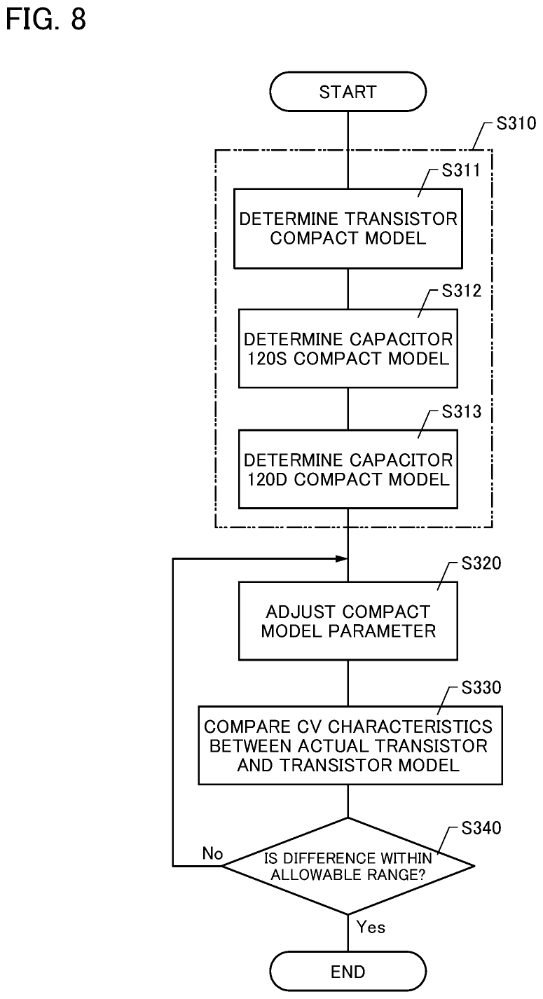

FIG. 8 is a flow chart for illustrating an operation example of the simulation device 200. In this embodiment, an example is described in which the simulation device 200 performs an operation for making setting parameters for the transistor model 100 approximate an actual transistor.

First, the transistor model 100 is generated according to user's instructions (Step S310). In this embodiment, the transistor model 100 is generated. More specifically, first, a compact model to be used as the transistor 110 is determined (Step S311). A compact model is a model in which device characteristics are mathematically expressed comparatively easily. Simulation accuracy is determined by the accuracy of the compact model. As transistor compact models, a variety of models such as BSIM3, BSIM4, BSIMSOI, HiSIM-HV, RPI-TFT, and HPATFT have been proposed. In this embodiment, RPI-TFT models are used.

Next, a compact model of the capacitor 120S is determined (Step S312). For example, in the case where semiconductor layers of the actual transistor to be made to approximate have a stacked structure and two electron affinities, the capacitor 120a is used as the capacitor 120S. Alternatively, in the case where the semiconductor layers of the actual transistor to be made to approximate have three electron affinities, the capacitor 120b is used as the capacitor 120S. For example, PI-TFT models are used as models of the transistor 121 that is included in the capacitor 120a and the transistor 121a and the transistor 121b that are included in the capacitor 120b. In this embodiment, a compact model made on the assumption that the capacitor 120b is used as the capacitor 120S is used.

Then, like the capacitor 120S, a compact model of the capacitor 120D is determined (Step S313). In this embodiment, a compact model made on the assumption that the capacitor 120b is used as the capacitor 120D is used. In this manner, the transistor model 100 can be generated.

Next, parameters for the compact models of the capacitor 120S and the capacitor 120D are adjusted so that the parameters are close to CV characteristics of gate capacitance of the actual transistor (Step S320). At the same time, parameters for the compact model of the transistor 110 may be adjusted.

Next, the CV characteristics of the gate capacitance of the actual transistor and CV characteristics of gate capacitance of the transistor model 100 are compared (Step S330).

Next, whether a difference between the CV characteristics of the gate capacitance of the actual transistor and the CV characteristics of the gate capacitance of the transistor model 100 is within the allowable range is compared (Step S340). In the case where the difference is out of the allowable range, the process returns to Step S320 and the parameters are adjusted again. In the case where the difference is within the allowable range, the operation for making the setting parameters for the transistor model 100 approximate the actual transistor is terminated.

When the setting parameters for the transistor model 100 are adjusted in this manner, the transistor model 100 can be made to approximate the actual transistor. The simulation device 200 has a program that achieves the above operation. In addition, the simulation device 200 has a variety of programs that verify a variety of circuit operations in addition to the program that achieves the above operation. Furthermore, the simulation device 200 can use results obtained by execution of one verification program for another verification program.

This embodiment can be implemented in an appropriate combination with structures described in the other embodiment, examples, and the like.

### EXAMPLE 1

The transistor 150D described in the above embodiment was manufactured, and CV characteristics of gate capacitance were measured. An In—Ga—Zn oxide was used as the semiconductor layer 530. Specifically, as the semiconductor layer 530c, a 5-nm-thick In—Ga—Zn oxide was formed by a sputtering method using a sputtering target having a composition of In:Ga:Zn=1:3:4. In addition, as the semiconductor layer 530b, a 15-nm-thick In—Ga—Zn oxide was formed by a sputtering method using a sputtering target having a composition of In:Ga:Zn=4:2:4.1. Furthermore, as the semiconductor layer 530a1, a 3-nm-thick In—Ga—Zn oxide was formed by a sputtering method using a sputtering target having a composition of In:Ga:Zn=4:2:4.1. Moreover, as the semiconductor layer 530a2, a 3-nm-thick In—Ga—Zn oxide was formed by a sputtering method using a sputtering target having a composition of In:Ga:Zn=1:3:4.

The CV characteristics of the gate capacitance were measured under the conditions that a source, a drain, and a back gate of the transistor were fixed to 0 V and a voltage applied to a gate (also referred to as a gate voltage or Vg) was changed from −3.3 V to 3.3 V.

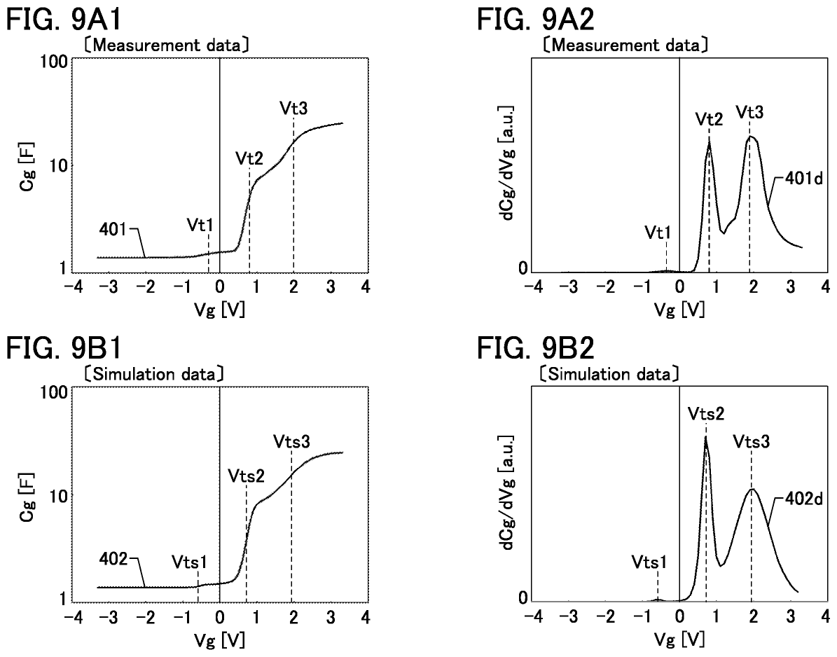

FIG. 9A1 shows a CV curve 401 that is a measurement result of the CV characteristics of the gate capacitance. The CV curve 401 is measurement data. In FIG. 9A1, a horizontal axis represents a linear axis showing a voltage value of the gate voltage (Vg), and a vertical axis represents a logarithmic axis showing a capacitance value of the gate capacitance (Cg). In addition, FIG. 9A2 shows a differential curve 401d where the CV curve 401 is differentiated by Vg. In FIG. 9A2, a horizontal axis represents a linear axis showing a voltage value of the gate voltage (Vg), and a vertical axis represents a linear axis showing the rate of change of the gate capacitance with respect to change of the gate voltage (dCg/dVg). In the CV curve 401d, three peaks (Vt1, Vt2, and Vt3) can be observed within the Vg range from −3.3 V to 3.3 V. Here, Vt1 was −0.3 V, Vt2 was 0.8 V, and Vt3 was 2.0 V.

Then, simulation of a CV curve that is made to approximate the CV curve 401 was performed using the transistor model 100. SPICE was used as a circuit simulator. In this example, the capacitor 120b was used as the capacitor 120S and the capacitor 120D included in the transistor model 100.

FIG. 9B1 shows a CV curve 402 that is formed using the transistor model 100. Thus, the CV curve 402 is simulation data. As in FIG. 9A1, in FIG. 9B1, a horizontal axis shows a voltage value of the gate voltage (Vg), and a vertical axis shows a capacitance value of the gate capacitance (Cg). In addition, FIG. 9B2 shows a differential curve 402d where the CV curve 402 is differentiated by Vg. As in FIG. 9A2, in FIG. 9B2, a horizontal axis shows a voltage value of the gate voltage (Vg), and a vertical axis shows the rate of change of the gate capacitance with respect to change of the gate voltage (dCg/dVg).

In the CV curve 402d, three peaks (Vts1, Vts2, and Vts3) can be observed within the Vg range from −3.3 V to 3.3 V. Here, Vts1 was −0.5 V, Vts2 was 0.7 V, and Vts3 was 1.9 V.

Values very close to those of Vt1, Vt2, and Vt3 were obtained as Vts1, Vts2, and Vts3, respectively. FIG. 9A1, FIG. 9A2, FIG. 9B1, and FIG. 9A2 reveal that, as the CV curve 402, a CV curve that is in good agreement with the CV curve 401 can be reproduced. With the use of the transistor model 100, an approximate curve (the CV curve 402) that favorably reproduces the CV curve 401, which is the measurement data, can be obtained.

### EXAMPLE 2

A ring oscillator where 51-stage inverters are connected was manufactured, and oscillation characteristics of the ring oscillator were measured.

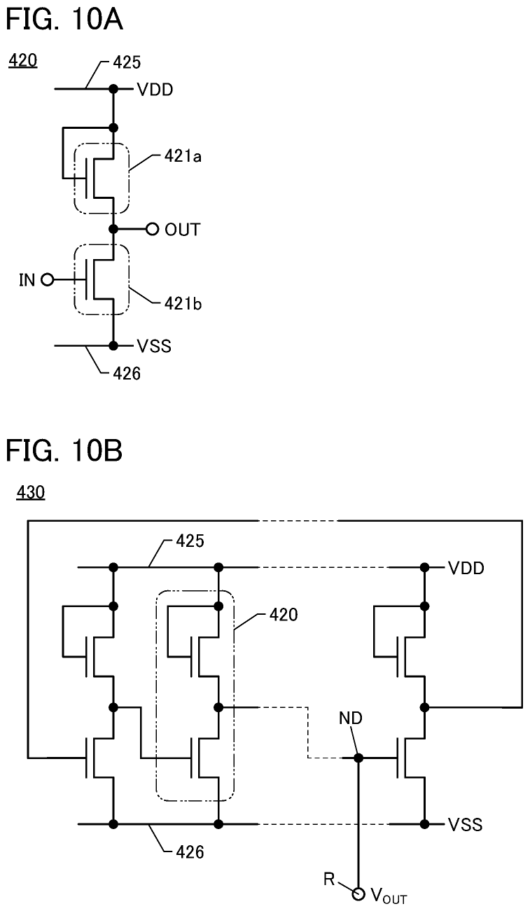

FIG. 10A illustrates an equivalent circuit diagram of an inverter 420. The inverter 420 has a structure where a transistor 421a and a transistor 421b are connected in series. One of a source and a drain of the transistor 421a is electrically connected to an output terminal OUT, and the other of the source and the drain of the transistor 421a is electrically connected to a wiring 425. A gate of the transistor 421a is electrically connected to the other of the source and the drain of the transistor 421a. Thus, the gate of the transistor 421a is electrically connected to the wiring 425. One of a source and a drain of the transistor 421b is electrically connected to the output terminal OUT, and the other of the source and the drain of the transistor 421b is electrically connected to a wiring 426. A gate of the transistor 421b is electrically connected to an input terminal IN. VDD is supplied to the wiring 425, and VSS is supplied to the wiring 426.

As the transistor 421a, a transistor that has the same structure as the transistor 150D described in Example 1 was used. In addition, one hundred transistors that are the same as the transistor 421a were connected in parallel and used as the transistor 421b in order to increase the channel width of the transistor 421b substantially.

FIG. 10B illustrates an equivalent circuit diagram of a ring oscillator 430. As described above, the ring oscillator 430 has a structure where 51-stage inverters 420 are connected. An output of the ring oscillator 430 can be extracted from a connection node ND of the two adjacent inverters 420. The ring oscillator 430 illustrated in FIG. 10B includes a terminal R electrically connected to the node ND, and an output voltage V_{OUT} of the ring oscillator 430 is supplied to the terminal R.

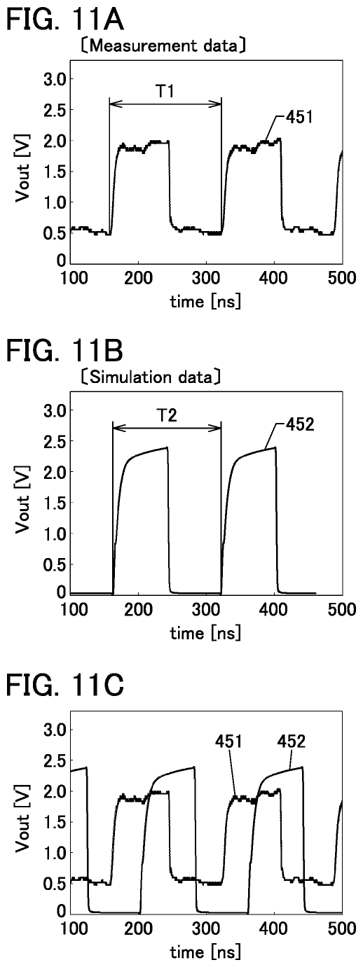

Oscillation characteristics of the ring oscillator 430 were measured under the conditions that 3.3 V was supplied to the wiring 425 as VDD and 0 V was supplied to the wiring 426 as VSS. FIG. 11A shows oscillation characteristics 451 (measurement data) of the ring oscillator 430. In FIG. 11A, a horizontal axis represents time, and a vertical axis represents the output voltage V_{OUT}. A transmission cycle T1 of the oscillation characteristics 451 was 163 ns.

Next, simulation of the oscillation characteristics of the ring oscillator 430 was performed using the transistor model 100. As in Example 1, SPICE was used as a circuit simulator. FIG. 11B shows oscillation characteristics 452 (simulation data) of the ring oscillator 430 obtained by the simulation. In FIG. 11B, a horizontal axis represents time, and a vertical axis represents the output voltage V_{OUT}. A transmission cycle T2 of the oscillation characteristics 452 was 159 ns.

FIG. 11C shows the oscillation characteristics 451 and the oscillation characteristics 452 overlapping with each other. In FIG. 11C, the oscillation characteristics 452 overlap with the oscillation characteristics 451 while being shifted by quarter of the cycle. FIG. 11A, FIG. 11B, and FIG. 11C reveal that the transmission cycles of the oscillation characteristics 451 and the oscillation characteristics 452 are equivalent and the oscillation characteristics are in good agreement with each other. With the use of the transistor model 100, approximate characteristics (the oscillation characteristics 452) that favorably reproduce the oscillation characteristics 451, which are the measurement data, can be obtained.

### REFERENCE NUMERALS

100: transistor model, 110: transistor, 121: transistor, 151: CV curve, 152: CV curve, 200: simulation device, 201: bus line, 210: control device, 220: arithmetic unit, 230: memory device, 240: auxiliary memory device, 250: input/output device, 260: communication device, 401: CV curve, 402: CV curve, 420: inverter, 425: wiring, 426: wiring, 430: ring oscillator, 451: oscillation characteristics, 452: oscillation characteristics, 120a: capacitor, 120b: capacitor, 120D: capacitor, 120S: capacitor, 121a: transistor, and 121b: transistor.

1. A method for forming a transistor model made to approximate characteristics of a field-effect transistor, comprising:
a first step of setting a field-effect transistor model including a gate, a source, and a drain;
a second step of setting a first capacitor between the gate and the source;
a third step of setting a second capacitor between the gate and the drain, and
a fourth step of making CV characteristics of the first capacitor and CV characteristics of the second capacitor approximate measured values of CV characteristics of gate capacitance of the field-effect transistor,
wherein each of the first capacitor and the second capacitor is a non-linear capacitor.

2. The method for forming a transistor model, according to claim 1,
wherein the first capacitor comprises a plurality of capacitors, and
wherein the second capacitor comprises a plurality of capacitors.

3. The method for forming a transistor model, according to claim 1,
wherein a capacitance value of each of the first capacitor and the second capacitor is determined depending on a gate voltage.

4. A program for executing the method for forming a transistor model, according to claim 1, on a computer.

5. A computer readable recording medium storing the program according to claim 4.

6. A simulation device made to approximate characteristics of a field-effect transistor, comprising:
setting a field-effect transistor model including a gate, a source, and a drain;
setting a first capacitor between the gate and the source;
setting a second capacitor between the gate and the drain, and
making CV characteristics of the first capacitor and CV characteristics of the second capacitor approximate measured values of CV characteristics of gate capacitance of the field-effect transistor,
wherein each of the first capacitor and the second capacitor is a non-linear capacitor.

7. The simulation device according to claim 6,
wherein the first capacitor comprises a plurality of capacitors, and
wherein the second capacitor comprises a plurality of capacitors.

8. The simulation device according to claim 6,
wherein a capacitance value of each of the first capacitor and the second capacitor is determined depending on a gate voltage.

9. A program making a computer function as the simulation device according to claim 6.

10. A computer readable recording medium storing the program according to claim 9.

11. A transistor model made to approximate characteristics of a field-effect transistor
wherein the field-effect transistor comprises a gate, a source, and a drain,
wherein a first capacitor is provided between the gate and the source,
wherein a second capacitor is provided between the gate and the drain, and
wherein each of the first capacitor and the second capacitor is a non-linear capacitor.

12. The transistor model according to claim 11,
wherein the first capacitor comprises a plurality of capacitors, and
wherein the second capacitor comprises a plurality of capacitors.

13. The transistor model according to claim 11,
wherein a capacitance value of each of the first capacitor and the second capacitor is determined depending on a gate voltage.
